(19) United States
(12) Patent Application Publication
(10) Pub. No.: US 2026/0156950 A1
(43) Pub. Date: Jun. 4, 2026

(54) FRONTSIDE-ILLUMINATED PHOTODIODE DEVICE

(71) Applicant: ELECTRONICS AND TELECOMMUNICATIONS RESEARCH INSTITUTE, Daejeon (KR)

(72) Inventors: Duk-Jun Kim, Daejeon (KR); Shinmo An, Daejeon (KR); Dong-Hun Lee, Daejeon (KR); Young-Tak Han, Daejeon (KR)

(21) Appl. No.: 19/409,531

(22) Filed: Dec. 4, 2025

(30) Foreign Application Priority Data
Nov. 29, 2024 (KR) 10-2024-0174791
Sep. 1, 2025 (KR) 10-2025-0122979

(51) Int. Cl. H10F 30/223; H10F 77/124; H10F 77/20; H10F 77/40

(52) U.S. Cl. CPC H10F 30/223; H10F 77/1248; H10F 77/206; H10F 77/413

(57) ABSTRACT

A frontside-illuminated photodiode device is provided. The frontside-illuminated photodiode device includes a substrate, a mesa structure formed on an upper surface of the substrate and including a light absorption layer absorbing incident light irradiated through an upper side thereof, and a metal coating layer of a non-plane structure formed on a lower surface of the substrate and reflecting incident light, which is not absorbed by the light absorption layer, to be again absorbed by the light absorption layer.

### CROSS-REFERENCE TO RELATED APPLICATIONS

This application claims the benefit of Korean Patent Application Nos. 10-2024-0174791 filed on Nov. 29, 2024, and 10-2025-0122979 filed on Sep. 1, 2025, which are hereby incorporated by reference as if fully set forth herein.

### BACKGROUND

### Field of the Invention

The present disclosure relates to a photodiode device, and more particularly, to a frontside-illuminated photodiode device.

### Discussion of the Related Art

In manufacturing optical receiver modules for optical communication, frontside-illuminated photodiode devices of a chip type where indium gallium arsenide (InGaAs) single crystal is adopted as a light absorption layer are being widely used. In such InGaAs photodiode devices, generally, an indium phosphide (InP) substrate where a group III-V compound semiconductor epitaxial growth layer of a p-i-n or n-i-p doping stack structure is formed is first manufactured, a photodiode structure is implemented in the InP substrate through a compound semiconductor etching process and a metal electrode formation process subsequently, and then, the InGaAs photodiode device is finished by performing a lapping process of decreasing a thickness of the InP substrate and a cleaving process of cutting the InP substrate to have a desired shape and size.

A mesa structure where an InGaAs light absorption layer is provided on the InP substrate is generally formed by the etching process to have a cylindrical shape or a shape similar to a cylindrical shape, and in this case, a process of irradiating light toward an upper portion of the mesa structure is referred to as frontside illumination, and a process of irradiating light toward a lower portion of the mesa structure is referred to as backside illumination. Also, whether to use a frontside-illuminated photodiode device chip or whether to use a backside-illuminated photodiode device chip in a module packaging process is determined based on a design structure of the optical receiver module.

Moreover, each of a 3 dB bandwidth and photoresponsivity is a significant indicator for evaluating an operation speed and an optoelectronic conversion performance of photodiode devices. Experimentally, a 3 dB bandwidth is defined as a measurement frequency where the power of an electrical signal generated through optoelectronic conversion of a photodiode device decreases by ½ with respect to a value of a measurement start frequency. Also, photoresponsivity is a criterion for the amount of photocurrent which is generated with optical power of a unit size incident on a photodiode device, and a unit thereof is A/W.

To enhance such photoresponsivity, it is favorable to increase a thickness of the InGaAs light absorption layer. However, the increase in thickness of the light absorption layer increases a transit time or a diffusion time which is consumed when electron or hole carriers generated by light absorption move out through a metal electrode which is present on the top or side of the mesa structure, and due to this, causes an undesired result of reducing a 3 dB bandwidth of a photodiode device. Therefore, it is required to develop technology which enhances photoresponsivity in a situation where a thickness of the light absorption layer is fixed.

### SUMMARY

The present disclosure is directed to providing a frontside-illuminated photodiode device which may enhance photoresponsivity by using metal mirror surface reflection occurring in an interface between a substrate and a metal coating layer.

To achieve these and other advantages in accordance with the purpose of the invention, as embodied and broadly described herein, there is provided a frontside-illuminated photodiode device including a substrate, a mesa structure formed on an upper surface of the substrate and including a light absorption layer absorbing incident light irradiated through an upper side thereof, and a metal coating layer of a non-plane structure formed on a lower surface of the substrate and reflecting a residual incident light, which has not been absorbed by the light absorption layer, in order to be absorbed by the light absorption layer.

In an embodiment, the lower surface of the substrate may be formed of a spherical surface or an aspherical surface.

In an embodiment, the metal coating layer of the non-plane structure may be formed in a convex lens shape.

In an embodiment, a reflective surface of the metal coating layer of the non-plane structure may be formed in a spherical or aspherical surface having a certain curvature radius.

In an embodiment, the light absorption layer may be disposed at a focus of the reflective surface.

In an embodiment, a thickness of the substrate is set so that the light absorption layer may be disposed at a focus of the reflective surface.

In another aspect of the present invention, there is provided a frontside-illuminated photodiode device including a substrate, a mesa structure formed on an upper surface of the substrate and including a light absorption layer absorbing incident light irradiated through an upper side thereof, a dielectric layer of a non-plane structure formed on a lower surface of the substate, and a metal coating layer of a non-plane structure formed on the lower surface of the dielectric layer and reflecting a residual incident light, which has not been absorbed by the light absorption layer, in order to be absorbed by the light absorption layer.

In an embodiment, the lower surface of the substrate, the dielectric layer of the non-plane structure, and the metal coating layer of the non-plane structure may be formed in a convex lens shape.

According to an embodiment of the present disclosure, because a metal coating layer causing metal mirror surface reflection is formed on a lower surface of a substrate included in a frontside-illuminated photodiode device, incident light irradiated from an upper portion of the frontside-illuminated photodiode device may be reflected by the metal coating layer and may be re-irradiated onto a light absorption layer included in a mesa structure formed on the substrate 100, and thus, the amount of incident light absorbed by the light absorption layer may considerably increase without an increase in thickness of the light absorption layer, thereby largely enhancing the photoresponsivity of the frontside-illuminated photodiode device.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

FIG. 1A is a plan view when a frontside-illuminated photodiode device according to an embodiment of the present disclosure is seen from above.

FIG. 1B is a cross-sectional view of the frontside-illuminated photodiode device taken along the line A-B of FIG. 1A.

FIG. 2 is a cross-sectional view of a frontside-illuminated photodiode device to which a metal coating layer is applied for improving photoresponsivity, according to an embodiment of the present disclosure.

FIG. 3 is a cross-sectional view of a frontside-illuminated photodiode device to which a metal coating layer is applied for improving photoresponsivity, according to another embodiment of the present disclosure.

FIG. 4 is a cross-sectional view of a frontside-illuminated photodiode device to which a metal coating layer is applied for improving photoresponsivity, according to another embodiment of the present disclosure.

### DETAILED DESCRIPTION OF THE INVENTION

In the following description, the technical terms are used only for explaining a specific embodiment while not limiting the present disclosure. The terms of a singular form may include plural forms unless referred to the contrary. The meaning of ‘comprise’, ‘include’, or ‘have’ specifies a property, a region, a fixed number, a step, a process, an element and/or a component but does not exclude other properties, regions, fixed numbers, steps, processes, elements and/or components.

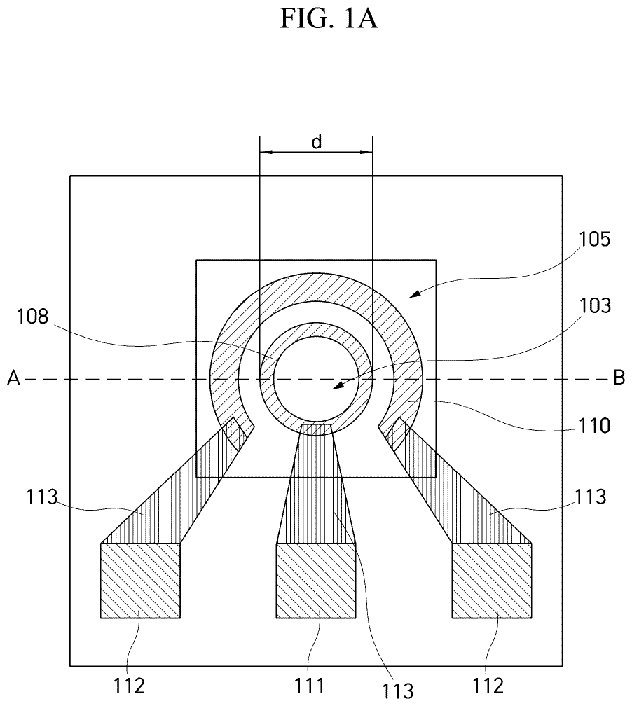

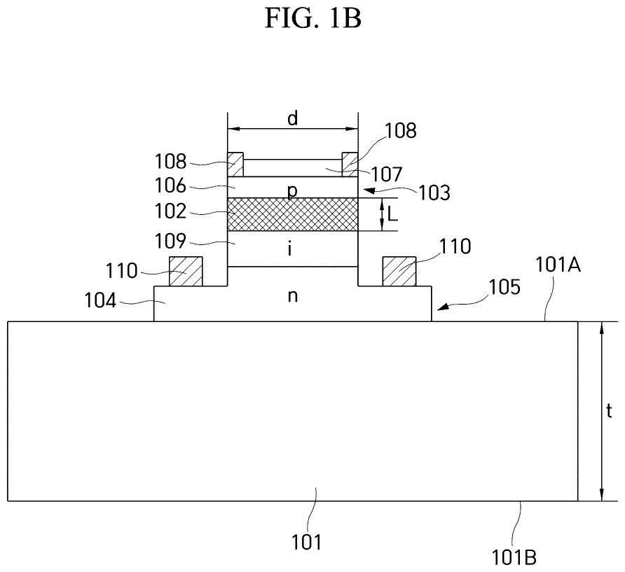

FIG. 1A is a plan view when a frontside-illuminated photodiode device according to an embodiment of the present disclosure is seen from above, and FIG. 1B is a cross-sectional view of the frontside-illuminated photodiode device taken along the line A-B of FIG. 1A.

Referring to FIGS. 1A and 1B, the frontside-illuminated photodiode device according to an embodiment of the present disclosure may include a substrate 101 and a mesa structure 103 and 105 which is formed on an upper surface 101A of the substrate 101.

The substrate 101 may have a thickness t and may be a substrate formed of a material which enables an epitaxial layer growth of a photodiode device, and for example, may be an indium phosphide (InP) substrate. In addition, the substrate 101 may be formed of a group III-V or IV semiconductor substrate such as gallium arsenide (GaAs), gallium nitride (GaN), or silicon (Si). In the present embodiment, the InP substrate may be described as an example, but is not limited thereto.

The mesa structure 103 and 105 may include a lower mesa structure which is formed on an upper surface of the InP substrate 101 and an upper mesa structure 103 which is formed on the lower mesa structure 105. The lower mesa structure 105 may be formed in a square or rectangular shape when viewed from above the substrate 101, and the upper mesa structure 103 may be formed in a cylindrical shape. An area of the lower mesa structure 105 may be formed to be greater than a cross-sectional area of the upper mesa structure 103. For example, when the diameter of the upper mesa structure 103 is d, the length and width of the lower mesa structure 105 may be formed to be greater than d.

The upper mesa structure 103 may include a light absorption layer 102 which has the diameter d and a thickness L. The light absorption layer 102 may perform a function of absorbing incident light (photon) to generate an electron-hole pair. The light absorption layer 102, for example, may be formed of a group III-V compound semiconductor of an indium gallium arsenide (InGaAs) group and may be formed of another light-absorbing material such as germanium (Ge), silicon germanium (SiGe), or gallium arsenide (GaAs) in addition to InGaAs, based on a light absorption characteristic. In the present embodiment, an InGaAs light absorption layer may be described as an example, but is not limited thereto.

The lower mesa structure 105 may include a first conductive-type epitaxial growth layer 104 which is formed through an etching process. In the present embodiment, the first conductive type may be referred to as n-type, and a second conductive type may be referred to as p-type.

Moreover, in the frontside-illuminated photodiode device according to an embodiment of the present disclosure, when a 3 dB bandwidth of 40 GHz or more is needed, it may be needed that the diameter d of the upper mesa structure 103 is designed to be less than 15 μm, in order to decrease a capacitance which is inversely proportional to a 3 dB bandwidth.

To provide a detailed description of the upper mesa structure 103, the upper mesa structure 103 may further include a second conductive-type (p-type) epitaxial growth layer 106 which is formed on the InGaAs light absorption layer 102, a dielectric layer 107 which is formed on the p-type epitaxial growth layer 106, and a second conductive-type (p-type) ohmic contact metal electrode pattern 108 which is formed on the p-type epitaxial growth layer 106 and has a circular band shape surrounding the dielectric layer 107. The dielectric layer 107 may perform a function of decreasing the reflection of incident light, and to this end, for example, the dielectric layer 107 may be formed of silicon nitride (Si₃N₄) or an equivalent material thereof.

Furthermore, the upper mesa structure 103 may further include a nonconductive-type epitaxial growth layer 109 which is formed under the InGaAs light absorption layer 102. Here, the nonconductive type may be referred to as i-type. The i-type epitaxial growth layer 109 may be formed in a structure where carrier doping is hardly provided, and thus, a depletion region between a p-type region and an n-type region may enlarge, thereby contributing to a reduction in a capacitance of a device. The n-type epitaxial growth layer 104 included in the lower mesa structure 105 described above may be formed under the i-type epitaxial growth layer 109.

A first conductive-type (n-type) ohmic contact metal electrode pattern 110 having a circular band shape partially surrounding the upper mesa structure 103 may be formed on an upper surface of the n-type epitaxial growth layer 104 exposed upward.

Moreover, as illustrated in FIG. 1A, a signal metal electrode pad 111 and a ground metal electrode pad 112 for outputting a photoelectric-converted electrical signal to the outside may be formed in the upper surface 101A of the InP substrate 101.

The electrode pads 111 and 112 may be electrically connected to the p-type ohmic contact metal electrode pattern 108 and/or the n-type ohmic contact metal electrode pattern 110 through metal wirings 113 which are formed in the upper surface 101A of the InP substrate 101.

In a case where incident light reaches the light absorption layer 102 by 100% without light reflection by using an anti-reflecting dielectric layer 107 which is provided in an uppermost portion of the upper mesa structure 103 of FIG. 1B, when the absorption coefficient and thickness of the light absorption layer 102, a light absorption rate A may be expressed as a relational equation “1−exp(−αL)”. Also, a photoresponsivity R of a photodiode device may be proportional to the light absorption rate A. Accordingly, the thickness L of the light absorption layer 102 should increase for increasing the photoresponsivity R.

On the other hand, as described above, when the thickness L of the light absorption layer 102 increases, an electron or hole carrier transit time and diffusion time of a photodiode device may increase, and due to this, a 3 dB bandwidth may decrease. Therefore, when a 3 dB bandwidth of 40 GHz or more is needed, it may be needed that the thickness L of the InGaAs light absorption layer 102 is designed to be 1.0 μm or less. In a case where the thickness L of the InGaAs light absorption layer 102 is 1.0 μm and a wavelength of incident light is 1.55 μm, when the absorption coefficient α of the InGaAs light absorption layer 102 is assumed to be 6,700 cm⁻¹, the light absorption rate A may be calculated to be about 0.45.

Furthermore, incident light which is not absorbed by the InGaAs light absorption layer 102 may sequentially pass through the i-type epitaxial growth layer 109, the n-type epitaxial growth layer 104, and the InP substrate 101, and then, the incident light may be reflected from an interface between air and a lower surface 101B of the InP substrate 101 with a reflectance of about 0.27, and a portion of the reflected light may be reabsorbed by the InGaAs light absorption layer 102.

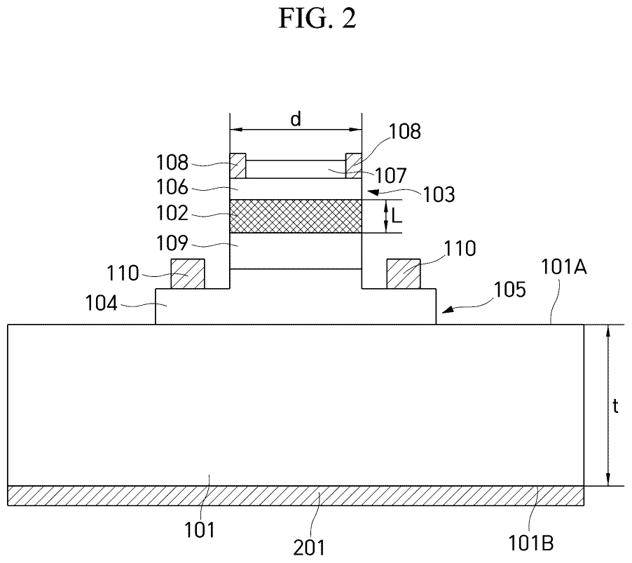

FIG. 2 is a cross-sectional view of a frontside-illuminated photodiode device to which a metal coating layer is applied for improving photoresponsivity, according to an embodiment of the present disclosure.

Referring to FIG. 2, except for that a flat metal coating layer 201 is formed on the lower surface 101B of the InP substrate 101, the photodiode device including a metal coating layer according to an embodiment of the present disclosure may be the same as the photodiode device of FIG. 1B.

The metal coating layer 201, for example, may be formed of gold (Au), silver (Ag), aluminum (Al), or an equivalent material thereof. The metal coating layer 201 formed of Au, Ag, or Al may form a high reflectance close to 1 in an interface with the InP substrate 101, and thus, incident light may be effectively reflected from a corresponding interface.

Therefore, comparing with the photodiode device of FIG. 1B, in the photodiode device of FIG. 2, the amount of reflected light from the InGaAs light absorption layer 102 may increase, and as the amount of light absorption increases, relatively higher photoresponsivity may be obtained.

Moreover, when light passing through the InGaAs light absorption layer 102 is completely collimated light, light reflected from an interface between the metal coating layer 201 and the InP substrate 101 may also be completely collimated light identically, and thus, may be precisely re-irradiated onto the InGaAs light absorption layer 102. In this case, light reabsorption may be maximized.

However, light passing through the light absorption layer 102 may not be completely collimated light, and the thickness t of the InP substrate 101 that have undergone a cleaving process may be 80 μm to 250 μm and thick generally, and thus, the amount of light resorbed by the light absorption layer 102 may be inevitably limited. Hereinafter, a method for solving such a problem will be described.

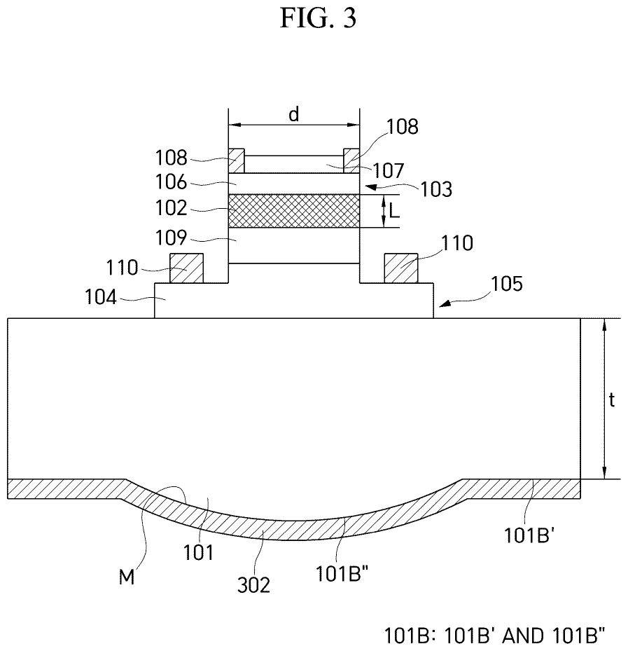

FIG. 3 is a cross-sectional view of a frontside-illuminated photodiode device to which a metal coating layer is applied for improving photoresponsivity, according to another embodiment of the present disclosure.

Referring to FIG. 3, except for that the lower surface 101B of the InP substrate 101 is formed of a plane 101B′ and a spherical surface 101B″, and the photodiode device includes a non-plane metal coating layer 302 formed on the lower surface 101B, the photodiode device according to another embodiment of the present disclosure may be the same as the photodiode device of FIG. 2, in order to maximize photoresponsivity. In this case, the non-plane metal coating layer 302 may be formed in a convex lens shape, based on a shape of the spherical surface 101B″. Here, the spherical surface 101B″ may be replaced with an aspherical surface such as a paraboloidal surface, an oval surface, or a free curved surface.

A method of forming a portion of the lower surface of the InP substrate 101 as the spherical surface 101B″ may use microfabrication technology. For example, the method may use a laser ablation process of ablating a lower surface of a substrate in a spherical shape by using a high-power femtosecond laser or a ultraviolet (UV) laser, a dry etching process of etching the lower surface of the substrate in a spherical shape by performing a reactive ion etching (RIE) process after forming an etch mask where a thickness distribution is in the lower surface of the substrate, and a wet etching process of forming a curvature in an etch surface of the substrate by using a diffusion limited reaction.

The non-plane metal coating layer 302 may be formed of Au, Ag, Al, or an equivalent metal thereof. A method of forming the metal layer 302 on the lower surface 101B (101B′ and 101B″) of the substrate 101 may use a thermal evaporation process or an E-beam evaporation process. Also, in order to enhance the adhesion of the metal layer 302, a titanium (Ti) or chromium (Cr) metal layer having a thickness which is thinner than a penetration depth of light may be first deposited on the lower surface 101B (101B′ and 101B″) of the substrate 101, and then, metal such as Au, Ag, or Al may be deposited thereon.

Incident light which sequentially passes through the dielectric layer 107 and the p-type epitaxial growth layer 106 and is not absorbed by the InGaAs light absorption layer 102 may sequentially pass through the i-type epitaxial growth layer 109, the n-type epitaxial growth layer 104, and the InP substrate 101, and then, may be reflected from an interface between the lower surface 101B of the InP substrate 101 and the non-plane metal coating layer 302 with a reflectance of about 1, and the reflected light may be focused into the InGaAs light absorption layer 102 and absorbed by the InGaAs light absorption layer 102.

When the non-plane metal coating layer 302 of a convex lens shape is appropriately designed, and reflected light is efficiently focused into the InGaAs light absorption layer 102, a light absorption rate may be approximated as 1−exp(−2αL). Also, like the frontside-illuminated photodiode device of FIG. 1B, when it is assumed that the thickness L of the InGaAs light absorption layer 102 is 1.0 μm, and the absorption coefficient α of the InGaAs light absorption layer 102 is 6,700 cm⁻¹, a light absorption rate of the photodiode device of FIG. 3 may be calculated to be about 0.73.

Therefore, the photoresponsivity of the frontside-illuminated photodiode device according to another embodiment of the present disclosure illustrated in FIG. 3 may maximally increase by about (0.73/0.45)=1.62 times, compared to the photoresponsivity of the frontside-illuminated photodiode device of FIG. 1B in terms of simple calculation.

Moreover, the non-plane metal coating layer 302 having a convex lens shape or the spherical surface 101B″ of the InP substrate 101 may be formed in a spherical or paraboloidal shape having a curvature radius R₀, and the light absorption layer 102 may be designed to be disposed near a focus (f=R₀/2) of a reflective surface M of the non-plane metal coating layer 302, and thus, reflected light may be efficiently focused into the light absorption layer 102. Here, the thickness t of the InP substrate 101 may be adjusted so that the light absorption layer 102 is disposed near the focus of the reflective surface M of the non-plane metal coating layer 302. Also, in the non-plane metal coating layer 302, a spherical shape for maximizing a re-irradiation probability of reflected light from the non-plane metal coating layer 302 may be optimized through a simulation.

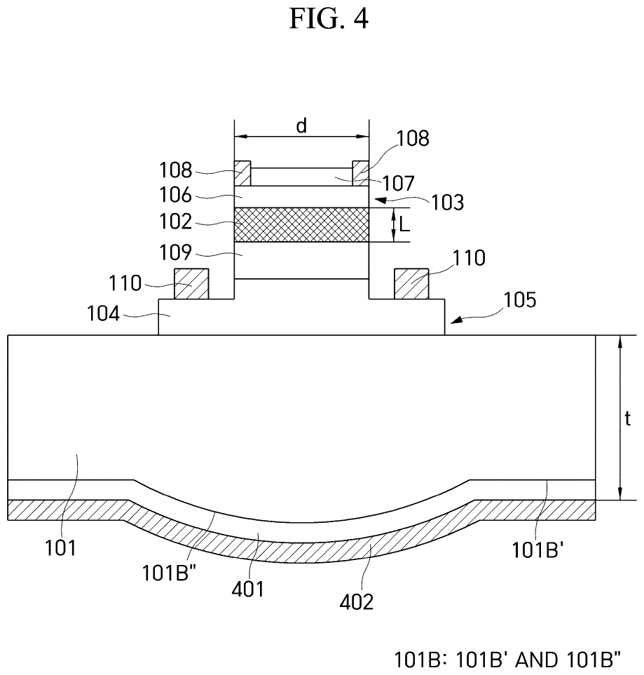

FIG. 4 is a cross-sectional view of a frontside-illuminated photodiode device to which a metal coating layer is applied for improving photoresponsivity, according to another embodiment of the present disclosure.

Referring to FIG. 4, except for that the photodiode device according to another embodiment of the present disclosure further includes a dielectric layer 401 formed between the lower surface 101B (101B′ and 101B″) of the InP substrate 101 and a non-plane metal coating layer 402, the photodiode device according to another embodiment of the present disclosure may be the same as the photodiode device of FIG. 3.

The dielectric layer 401 may be formed in a convex lens shape, based on a shape of the spherical shape 101B″, and may have the same function as that of the dielectric layer 107 included in the upper mesa structure 103. The dielectric layer 401 may be formed of the same material as that of the dielectric layer 107. For example, the dielectric layer 401 may be formed of Si₃N₄, but is not limited thereto and may be formed of several other dielectric materials such as Al₂O₃, TiO₂, and SiO₂. Also, the dielectric layer 401 may be implemented as an anti-reflecting dielectric layer by stacking the dielectric materials.

Incident light which sequentially passes through the dielectric layer 107 and the p-type epitaxial growth layer 106 and is not absorbed by the InGaAs light absorption layer 102 may sequentially pass through the i-type epitaxial growth layer 109, the n-type epitaxial growth layer 104, the InP substrate 101, and the dielectric layer 401, and then, may be reflected from an interface between the dielectric layer 401 and the non-plane metal coating layer 402 with a reflectance of about 1, and the reflected light may be focused into the InGaAs light absorption layer 102 and may be absorbed by the InGaAs light absorption layer 102.

When the curved surface 101B″ of a convex lens shape, the dielectric layer 401, and the non-plane metal coating layer 402 are appropriately designed, and a reflected light which is reflected by 100% in the dielectric layer 401 and the non-plane metal coating layer 402 without light absorption is focused by 100% into the InGaAs light absorption layer 102, the light absorption rate A may be approximated as 1−exp(−2αL). Also, like the frontside-illuminated photodiode device of FIG. 1B, when it is assumed that the thickness L of the InGaAs light absorption layer 102 is 1.0 μm, and the absorption coefficient α of the InGaAs light absorption layer 102 is 6,700 cm⁻¹, the light absorption rate A of the photodiode device of FIG. 4 may be calculated to be about 0.73.

Therefore, the photoresponsivity of the frontside-illuminated photodiode device according to another embodiment of the present disclosure illustrated in FIG. 4 may maximally increase by about (0.73/0.45)=1.62 times, compared to the photoresponsivity of the frontside-illuminated photodiode device of FIG. 1B in terms of simple calculation.

According to an embodiment of the present disclosure, because a metal coating layer causing metal mirror surface reflection is formed on a lower surface of a substrate included in a frontside-illuminated photodiode device, incident light irradiated from an upper portion of the frontside-illuminated photodiode device may be reflected by the metal coating layer and may be re-irradiated onto a light absorption layer included in a mesa structure formed on the substrate 100, and thus, the amount of incident light absorbed by the light absorption layer may considerably increase without an increase in thickness of the light absorption layer, thereby largely enhancing the photoresponsivity of the frontside-illuminated photodiode device.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A frontside-illuminated photodiode device comprising:
a substrate;
a mesa structure formed on an upper surface of the substrate and including a light absorption layer absorbing incident light irradiated through an upper side thereof; and
a metal coating layer of a non-plane structure formed on a lower surface of the substrate and reflecting a residual incident light, which has not been absorbed by the light absorption layer, in order to be absorbed by the light absorption layer.

2. The frontside-illuminated photodiode device of claim 1, wherein the lower surface of the substrate is formed of a spherical surface or an aspherical surface.

3. The frontside-illuminated photodiode device of claim 1, wherein the metal coating layer of the non-plane structure is formed in a convex lens shape.

4. The frontside-illuminated photodiode device of claim 1, wherein a reflective surface of the metal coating layer of the non-plane structure is formed in a spherical or aspherical surface having a certain curvature radius.

5. The frontside-illuminated photodiode device of claim 4, wherein the light absorption layer is disposed at a focus of the reflective surface.

6. The frontside-illuminated photodiode device of claim 4, wherein a thickness of the substrate is set so that the light absorption layer is disposed at a focus of the reflective surface.

7. A frontside-illuminated photodiode device comprising:
a substrate;
a mesa structure formed on an upper surface of the substrate and including a light absorption layer absorbing incident light irradiated through an upper side thereof;
a dielectric layer of a non-plane structure formed on a lower surface of the substate; and
a metal coating layer of a non-plane structure formed on the lower surface of the dielectric layer and reflecting a residual incident light, which has not been absorbed by the light absorption layer, in order to be absorbed by the light absorption layer.

8. The frontside-illuminated photodiode device of claim 7, wherein the lower surface of the substrate, the dielectric layer of the non-plane structure, and the metal coating layer of the non-plane structure are formed in a convex lens shape.

9. The frontside-illuminated photodiode device of claim 7, wherein a reflective surface of the metal coating layer of the non-plane structure is formed in a spherical or aspherical surface having a certain curvature radius.

10. The frontside-illuminated photodiode device of claim 9, wherein the light absorption layer is disposed at a focus of the reflective surface.

11. The frontside-illuminated photodiode device of claim 9, wherein a thickness of the substrate is set so that the light absorption layer is disposed at a focus of the reflective surface.
